(19) United States
(12) Patent Application Publication
(10) Pub. No.: US 2011/0186631 A1
(43) Pub. Date: Aug. 4, 2011

(54) METHOD FOR SETTING OPERATING FREQUENCY OF MEMORY CARD AND RELATED CARD READING APPARATUS

(76) Inventors: Chia-Jung Hsu, Taipei City (TW); Kun-Pin Lai, Hsin-Chu City (TW); Chi-Tai Wu, Taipei City (TW)

(21) Appl. No.: 12/721,498

(22) Filed: Mar. 10, 2010

(30) Foreign Application Priority Data
Feb. 3, 2010 (TW) 099103167

(51) Int. Cl. G06F 17/00; G06K 7/00; G11C 29/08; G06F 11/26

(52) U.S. Cl. 235/435; 714/718; 714/E11.159

(57) ABSTRACT

A method for setting an operating frequency of a memory card includes the following steps: performing an operating frequency adjusting flow to select a target operating frequency, and utilizing the target operating frequency to set the operating frequency of the memory card, where the step of performing the operating frequency adjusting flow includes: selecting a plurality of candidate operating frequencies; testing an accessing performance of the memory card operated under the plurality of candidate operating frequencies to generate a plurality of testing results, respectively; and selecting one of the plurality of candidate operating frequencies as the target operating frequency according to the plurality of testing results.

### BACKGROUND OF THE INVENTION

1. Field of the Invention

The present invention relates to a method for setting a memory card and related card reading apparatus, and more particularly, to a method for setting an operating frequency of a memory card and related card reading apparatus.

2. Description of the Prior Art

For many years, data storage devices have been an indispensable part of computer systems. Owing to different functions, the kinds of data storage devices available are numerous. As the sizes of these data storage devices are continually reduced, they appear in a variety of portable data storage devices, such as flash memory cards and external hard disk drives. Due to convenience of usage and the fact that data storage devices usually need to be coupled to a computer system, there are many external interface apparatuses developed to be provide convenient means for connecting the data storage devices. In this way, when an external interface apparatus is employed by the computer system, the computer system can access a connected data storage device quickly and easily. Usually, these external interface devices support several data storage devices with different kinds of interfaces. Flash memory cards can be accessed by various external access devices due to a variety of flash memory card standards. An external access device for supporting several kinds of flash memory cards is usually called memory card reader.

Secure digital (SD) memory card is a memory card format, and is widely used in portable devices, such as digital cameras, personal digital assistants (PDA) and multimedia players. The SD memory card is developed based on a format of a multimedia card (MMC), and has higher data transmission speed than that of the MMC. In addition, the specification of the SD memory card is updated continuously. The latest specification of the SD memory card is SDA3.0 specified by the SD card association (SDA), where the highest operating frequency specified by the SDA3.0 is 208 MHz, which is up to four times greater than the highest operating frequency (50 MHz) specified by the SDA2.0. Although the memory card operated at higher operating frequency has better accessing performance, the power consumption and electromagnetic interference (EMI) phenomenon of the memory card will be increased inevitably. Besides, in some situations, if the memory card compliant with the SDA2.0 specification only operates under the highest operating frequency (50 MHz) specified by the SDA2.0, the memory card may not obtain the optimal performance. In the above-mentioned situation, if the memory card can perform an over-clocking operation to work under an increased operating frequency falling within a permitted operating frequency range, the accessing performance of the memory card can be improved. Therefore, if the operating frequency of the memory card can be adjusted in a flexible manner without affecting the accessing performance of the memory card or exceeding the permitted operating frequency range of the memory card, the power consumption and EMI phenomenon of the memory card can be effectively decreased or the accessing performance of the memory card can be greatly improved.

### SUMMARY OF THE INVENTION

It is therefore one of the objectives of the present invention to provide a method for setting an operating frequency of a memory card and related card reading apparatus, to solve the above mentioned problems.

According to an embodiment of the present invention, an exemplary method for setting an operating frequency of a memory card is disclosed. The exemplary method includes the following steps: performing an operating frequency adjusting flow to select a target operating frequency; and utilizing the target operating frequency to set the operating frequency of the memory card. Wherein the step of performing the operating frequency adjusting flow includes: selecting a plurality of candidate operating frequencies; testing an accessing performance of the memory card operated under the plurality of candidate operating frequencies to generate a plurality of testing results, respectively; and selecting one of the plurality of candidate operating frequencies as the target operating frequency according to the plurality of testing results.

According to another embodiment of the present invention, an exemplary card reading apparatus for accessing a memory card is disclosed. The exemplary card reading apparatus includes a storage device and a processor. The storage device stores a programming code. The processor is coupled to the storage device, and when the programming code is executed by the processor, the processor is operative to perform the following steps: performing an operating frequency adjusting flow to select a target operating frequency; and utilizing the target operating frequency to set the operating frequency of the memory card. Wherein the step of performing the operating frequency adjusting flow includes: selecting a plurality of candidate operating frequencies; testing an accessing performance of the memory card operated under the plurality of candidate operating frequencies to generate a plurality of testing results, respectively; and selecting one of the plurality of candidate operating frequencies as the target operating frequency according to the plurality of testing results.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a card reading apparatus according to an exemplary embodiment of the present invention.

FIG. 2 is a flowchart illustrating a method for setting an operating frequency of a memory card according to an exemplary embodiment of the present invention.

### DETAILED DESCRIPTION

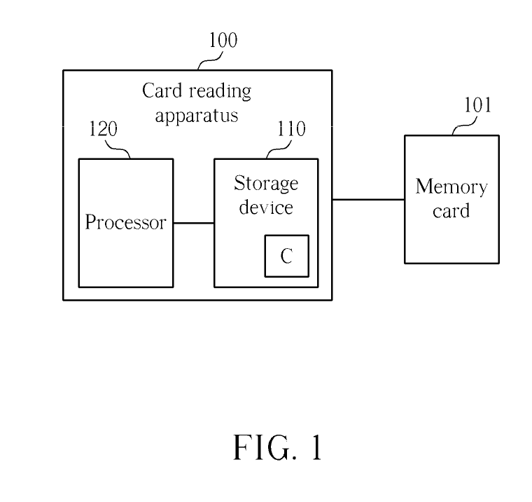

Please refer to FIG. 1. FIG. 1 is a diagram illustrating a card reading apparatus 100 according to an exemplary embodiment of the present invention. The card reading apparatus (e.g., a card reader) 100 is used for accessing at least a memory card 101. The card reading apparatus 100 includes, but is not limited to, a storage device 110 and a processor 120. The storage device 110 stores a programming code C. The processor 120 is coupled to the storage device 110, and when the programming code C is executed by the processor 120, the processor 120 is operative to perform the following steps: performing an operating frequency adjusting flow to select a target operating frequency F_{target} and utilizing the target operating frequency F_{target} to set the operating frequency Fₒₚₑᵣₐₜₑ of the memory card 101, wherein the step of performing the operating frequency adjusting flow includes: selecting a plurality of candidate operating frequencies F_{candidate1}-F_{candidateN}; testing an accessing performance of the memory card 101 operated under the plurality of candidate operating frequencies F_{candidate1}-F_{candidateN} to generate a plurality of testing results D₁-D_{N}, respectively; and selecting one of the plurality of candidate operating frequencies F_{candidate1}-F_{candidateN} as the target operating frequency F_{target} according to the plurality of testing results D₁-D_{N}. Please note that, in this embodiment, the storage device 110 is implemented in the card reading apparatus 100 and the programming code C is stored in the storage device 110; however, this is for illustrative purposes only, and is by no means to serve as a limitation to the scope of the present invention. For example, the storage device 110 may be implemented in a computer system according to the actual design requirements. The design depends on whether the programming code C used for driving the card reading apparatus 100 is implemented by firmware built in the card reading apparatus 100 or the programming code C is implemented by software which is obtained via an interface (e.g., a PCI Express interface) connected to the card reading apparatus 100.

In this exemplary embodiment, the memory card 101 is a secure digital (SD) memory card compliant with the SDA3.0 specification, and the card reading apparatus 100 not only provides the operating frequencies of 25 MHz, 50 MHz, 100 MHz and 208 MHz which are compliant with the SDA3.0 specification, but also provides three extra operating frequencies of 125 MHz, 156 MHz and 178 MHz, where the above-mentioned seven operating frequencies represent the candidate operating frequencies F_{candidate1}-F_{candidate7} in a decreasing order of frequency, respectively. That is the operating frequency equal to 208 MHz is represented by F_{candidate1}, the operating frequency equal to 178 MHz is represented by F_{candidate2}, and so on. Please note that, this embodiment merely serves as an example for illustrating the technique features of the present invention, and should not be taken as a limitation to the scope of the present invention. In another exemplary embodiment, the card reading apparatus 100 can provide a different number of operating frequencies with different values as the candidate operating frequencies according to the actual design requirements.

When the memory card 101 is coupled to the card reading apparatus 100 and accessed by the card reading apparatus 100, the processor 120 of the card reading apparatus 100 performs the operating frequency adjusting flow to select a target operating frequency F_{target}. First, the processor 120 selects three candidate operating frequencies F_{candidate1}, F_{candidate2} and F_{candidate3} (which represent the operating frequencies of 208 MHz, 178 MHz and 156 MHz, respectively), and then the processor 120 tests the accessing performance of the memory card 101 operated under the candidate operating frequencies F_{candidate1}, F_{candidate2} and F_{candidate3} to generate the testing results D₁, D₂ and D₃, respectively. When the differences between the testing results D₁, D₂ and D₃ all fall within a predetermined range, the processor 120 selects the lowest operating frequency (i.e., the candidate operating frequencies F_{candidate3}) of the candidate operating frequencies F_{candidate1}, F_{candidate2} and F_{candidate3}, respectively corresponding to the testing results D₁, D₂ and D₃, as the target operating frequency F_{target}. When only the difference between the testing results D₁ and D₂ falls within the predetermined range, the processor 120 selects the lowest operating frequency (i.e., the candidate operating frequencies F_{candidate2}) of the candidate operating frequencies F_{candidate1} and F_{candidate2}, respectively corresponding to the testing results D₁ and D₂, as the target operating frequency F_{target}. When only the difference between the testing results D₂ and D₃ falls within the predetermined range, the processor 120 selects the lowest operating frequency (i.e., the candidate operating frequencies F_{candidate3}) of the candidate operating frequencies F_{candidate2} and F_{candidate3}, respectively corresponding to the testing results D₂ and D₃, as the target operating frequency F_{target}. Otherwise, the processor 120 selects the highest operating frequency (i.e., the candidate operating frequencies F_{candidate1}) of the candidate operating frequencies F_{candidate1}, F_{candidate2} and F_{candidate3}, respectively corresponded to the testing results D₁, D₂ and D₃, as the target operating frequency F_{target}. Please note that, in this exemplary embodiment, the processor 120 selects from the highest selectable operating frequency to lower operating frequencies sequentially, for selecting three candidate operating frequencies to test the accessing performance of the memory card 101, and the processor 120 selects the target operating frequency by checking if the differences between the testing results fall within a predetermined range. However, this should not be taken as a limitation of the present invention. In another exemplary embodiment, the processor 120 may select any number of operating frequencies to test the memory card 101, and selects the target operating frequency according to the actual requirements and the testing results. This alternative design should also fall within the scope of the present invention.

Finally, the processor 120 utilizes the selected target operating frequency F_{target} to set the operating frequency Fₒₚₑᵣₐₜₑ of the memory card 101, and records the selected target operating frequency F_{target} into the storage device 110. If the memory card 101 operated under the selected target operating frequency F_{target} has a timing error, the processor 120 will perform the operating frequency adjusting flow again to select and test other three candidate operating frequencies which have frequency values lower than that of the above-mentioned selected target operating frequency F_{target} to update the target operating frequency F_{target}, and record the updated target operating frequency F_{target} into the storage device 110. In this way, when the memory card 101 is coupled to the card reading apparatus 100 and accessed by the card reading apparatus 100 once again, the processor 120 can read the recorded target operating frequency F_{target} from the storage device 110 to set the operating frequency Fₒₚₑᵣₐₜₑ of the memory card 101 directly, and does not need to perform the above-mentioned operating frequency adjusting flow again, thereby improving the accessing performance of the memory card 101 greatly.

In another exemplary embodiment of the present invention, the memory card 101 is an SD memory card compliant with the SDA2.0 specification, and the card reading apparatus 100 not only provides two typical operating frequencies of 25 MHz, 50 MHz compliant with the SDA2.0 specification, but also provides the extra five operating frequencies of 83 MHz, 100 MHz, 125 MHz, 156 MHz and 178 MHz, where the above-mentioned seven operating frequencies represent the candidate operating frequencies F_{candidate1}-F_{candidate7} in an increasing order of frequency, respectively. That is, the operating frequency equal to 25 MHz is represented by F_{candidate1}, the operating frequency equal to 50 MHz is represented by F_{candidate2}, and so on.

When the memory card 101 is coupled to the card reading apparatus 100 and accessed by the card reading apparatus 100, the processor 120 performs the operating frequency adjusting flow to select the target operating frequency F_{target}. First, the processor 120 selects three candidate operating frequencies F_{candidate1}, F_{candidate2} and F_{candidate3} (which represent the operating frequencies of 25 MHz, 50 MHz and 83 MHz, respectively), and then the processor 120 tests the accessing performance of the memory card 101 operated under the candidate operating frequencies F_{candidate1} F_{candidate2} and F_{candidate3} to generate the testing results D₁, D₂ and D₃, respectively. When the differences between the testing results D₁, D₂ and D₃ all fall within a predetermined range and the values of the testing results D₁, D₂ and D₃ are all higher than a specific accessing performance value, the processor 120 selects the lowest operating frequency (i.e., the candidate operating frequencies F_{candidate1}) of the candidate operating frequencies F_{candidate1}, F_{candidate2} and F_{candidate3}, respectively corresponding to the testing results D₁, D₂ and D₃, as the target operating frequency F_{target}. When only the difference between the testing results D₂ and D₃ falls within the predetermined range and the values of the testing results D₂, D₃ are higher than the specific accessing performance value, the processor 120 selects the lowest operating frequency (i.e., the candidate operating frequencies F_{candidate2}) of the candidate operating frequencies F_{candidate2} and F_{candidate3}, respectively corresponding to the testing results D₂ and D₃, as the target operating frequency F_{target}. When only the value of the testing result D₃ is higher than the specific accessing performance value, the processor 120 selects the candidate operating frequency F_{candidate3} corresponding to the testing results D₃ as the target operating frequency F_{target}. Otherwise, the processor 120 performs the operating frequency adjusting flow again to select and test other three candidate operating frequencies F_{candidate4}, F_{candidate5} and F_{candidate6}, for selecting the target operating frequency F_{target}. Please note that, in this exemplary embodiment, the processor 120 selects from the lowest selectable operating frequency to higher operating frequencies sequentially, for selecting three candidate operating frequencies to test the accessing performance of the memory card 101, and the processor 120 selects the target operating frequency by checking if the differences between the testing results fall within a predetermined range and the values of the testing results are higher than a specific accessing performance value. However, this should not be taken as a limitation of the present invention.

Finally, the processor 120 utilizes the selected target operating frequency F_{target} to set the operating frequency Fₒₚₑᵣₐₜₑ of the memory card 101, and records the selected target operating frequency F_{target} into the storage device 110. Similarly, if the memory card 101 operated under the selected target operating frequency F_{target} has a timing error, the processor 120 will perform the operating frequency adjusting flow once again to update the target operating frequency F_{target}, and record the updated target operating frequency F_{target} into the storage device 110. In this way, when the memory card 101 is coupled to the card reading apparatus 100 and accessed by the card reading apparatus 100 again, the processor 120 can read the recorded target operating frequency F_{target} from the storage device 110 to set the operating frequency Fₒₚₑᵣₐₜₑ of the memory card 101 directly.

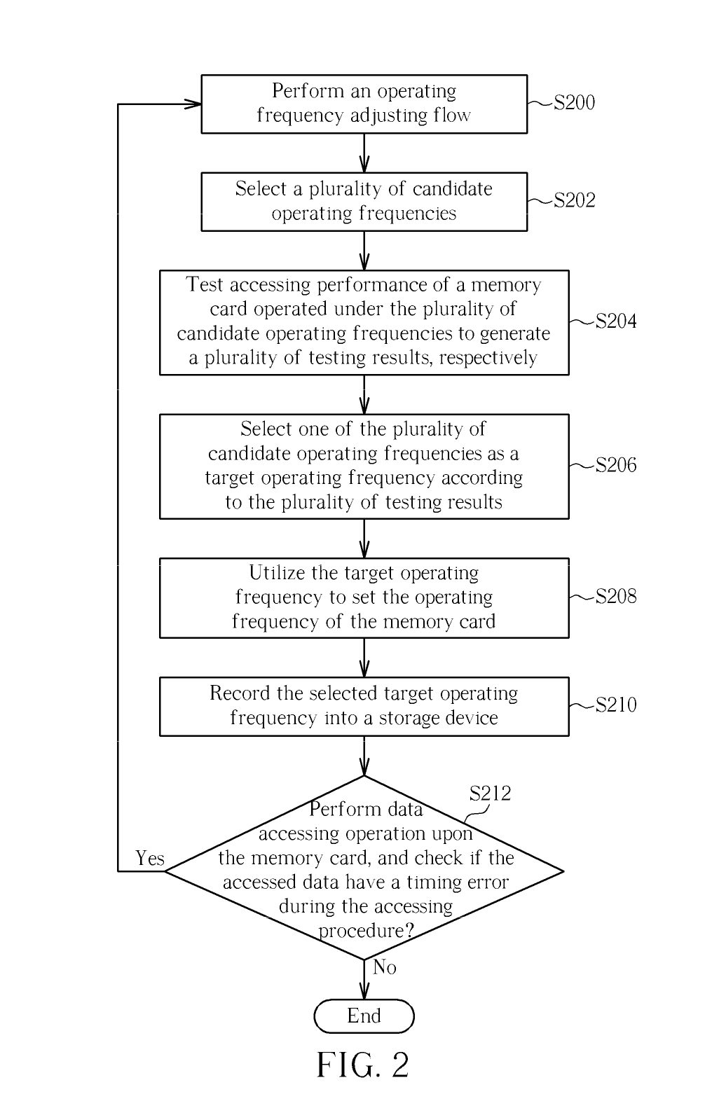

Please refer to FIG. 2. FIG. 2 is a flowchart illustrating a method for setting an operating frequency of the memory card 101 according to an exemplary embodiment of the present invention. Please refer to the card reading apparatus 100 shown in FIG. 1 in conjunction with the flowchart shown in FIG. 2. The exemplary method for setting the operating frequency of the memory card 101 includes the following steps:

Step 200: Perform an operating frequency adjusting flow.

Step 202: Select a plurality of candidate operating frequencies F_{candidate1}-F_{candidateN}.

Step 204: Test accessing performance of the memory card 101 operated under the plurality of candidate operating frequencies F_{candidate1}-F_{candidateN} to generate a plurality of testing results D₁-D_{N}, respectively.

Step 206: Select one of the plurality of candidate operating frequencies F_{candidate1}-F_{candidateN} as a target operating frequency F_{target} according to the plurality of testing results D₁-D_{N}.

Step 208: Utilize the target operating frequency F_{target} to set the operating frequency of the memory card 101.

Step 210: Record the selected target operating frequency F_{target} into the storage device 110.

Step 212: Perform data accessing operation upon the memory card 101, and check if the accessed data have a timing error during the accessing procedure. If the timing error occurs, the flow proceeds with step 200 again to update the target operating frequency F_{target}.

As those skilled in this art can easily understand the operations of steps 200-212 of the exemplary method after reading the disclosure of the card reading apparatus 100 shown in FIG. 1, full details are omitted here for brevity. Please note that the steps of the flowchart mentioned above are merely a practicable embodiment of the present invention, and should not be taken as a limitation of the present invention. The method can include other intermediate steps or can merge several steps into a single step without departing from the spirit of the present invention.

In summary, the present invention provides a method for setting an operating frequency of a memory card and related card reading apparatus. The present invention selects a plurality of candidate operating frequencies, and tests the accessing performance of the memory card operated under the plurality of candidate operating frequencies to generate a plurality of testing results, and then analyzes and compares the testing results to select a proper operating frequency for the memory card. Taking an SD memory card compliant with the SDA3.0 specification for example, when the difference between the accessing performances of the memory card operated under the two different candidate operating frequencies falls within a predetermined range, a lower operating frequency can be selected to set as the operating frequency of the SD memory card (i.e., an under-clocking operation is enabled), therefore, the power consumption and EMI phenomenon of the memory card can be significantly decreased. In addition, taking an SD memory card compliant with the SDA2.0 specification for example, the memory card can be operated at a higher frequency than it was designed for or was specified by the manufacturer to derive better accessing performance (i.e., an over-clocking operation is performed). Therefore, the present invention can adjust an operating frequency of a memory card in a flexible manner, and reduce the power consumption and EMI phenomenon without affecting the accessing performance of the memory card or increase the accessing performance under an operating frequency falling within a permitted frequency range of the memory card.

Those skilled in the art will readily observe that numerous modifications and alterations of the device and method may be made while retaining the teachings of the invention.

What is claimed is:

1. A method for setting an operating frequency of a memory card, comprising:
performing an operating frequency adjusting flow, comprising:
selecting a plurality of candidate operating frequencies;
testing an accessing performance of the memory card operated under the plurality of candidate operating frequencies to generate a plurality of testing results, respectively; and
selecting one of the plurality of candidate operating frequencies as a target operating frequency according to the plurality of testing results; and
utilizing the target operating frequency to set the operating frequency of the memory card.

2. The method of claim 1, wherein the step of selecting one of the plurality of candidate operating frequencies as the target operating frequency comprises:
selecting a lowest operating frequency of a plurality of operating frequencies, respectively corresponding to a plurality of specific testing results, as the target operating frequency when the plurality of specific testing results are included in the plurality of testing results and differences between the specific testing results all fall within a predetermined range; otherwise, selecting a highest operating frequency of the plurality of candidate operating frequencies as the target operating frequency.

3. The method of claim 1, wherein the step of selecting the plurality of candidate operating frequencies comprises:
selecting from a highest selectable operating frequency to lower operating frequencies sequentially.

4. The method of claim 1, further comprising:
when the memory card operated under the selected target operating frequency has a timing error, performing the operating frequency adjusting flow again to update the target operating frequency.

5. The method of claim 1, wherein the operating frequency adjusting flow further comprises:
recording the selected target operating frequency of the memory card.

6. The method of claim 1, wherein the step of selecting the plurality of candidate operating frequencies comprises:
in addition to all of operating frequencies specified by a specification of the memory card, providing at least one extra operating frequency; and
selecting the plurality of candidate operating frequencies from all of the at least one extra operating frequency and the operating frequencies specified by the specification of the memory card.

7. A card reading apparatus for accessing a memory card, comprising:
a storage device, for storing a programming code; and
a processor, coupled to the storage device, wherein the programming code executed by the processor causes the processor to perform the following steps:
performing an operating frequency adjusting flow, comprising:
selecting a plurality of candidate operating frequencies;
testing an accessing performance of the memory card operated under the plurality of candidate operating frequencies to generate a plurality of testing results, respectively; and
selecting one of the plurality of candidate operating frequencies as a target operating frequency according to the plurality of testing results; and
utilizing the target operating frequency to set the operating frequency of the memory card.

8. The card reading apparatus of claim 7, wherein the step of selecting one of the plurality of candidate operating frequencies as the target operating frequency comprises:
selecting a lowest operating frequency of a plurality of operating frequencies, respectively corresponding to a plurality of specific testing results, as the target operating frequency when the plurality of specific testing results are included in the plurality of testing results and differences between the specific testing results all fall within a predetermined range; otherwise, selecting a highest operating frequency of the plurality of candidate operating frequencies as the target operating frequency.

9. The card reading apparatus of claim 7, wherein the step of selecting the plurality of candidate operating frequencies comprises:
selecting from a highest selectable operating frequency to lower operating frequencies sequentially.

10. The card reading apparatus of claim 7, wherein the programming code executed by the processor further causes the processor to perform the following step:
when the memory card operated under the selected target operating frequency has a timing error, performing the operating frequency adjusting flow again to update the target operating frequency.

11. The card reading apparatus of claim 7, wherein the operating frequency adjusting flow further comprises:
recording the selected target operating frequency of the memory card; and
when the memory card is coupled to the card reading apparatus once again and accessed by the card reading apparatus, the programming code executed by the processor further causes the processor to perform the following step:
reading the recorded target operating frequency from the storage device to set the operating frequency of the memory card directly.

12. The card reading apparatus of claim 7, wherein the step of selecting the plurality of candidate operating frequencies comprises:
in addition to all of operating frequencies specified by a specification of the memory card, providing at least one extra operating frequency; and
selecting the plurality of candidate operating frequencies from all of the at least one extra operating frequency and the operating frequencies specified by the specification of the memory card.
